(19) United States
(12) Patent Application Publication
(10) Pub. No.: US 2026/0323833 A1
(43) Pub. Date: Oct. 15, 2026

(54) ADDITIVELY MANUFACTURED ELECTRONICS PACKAGING

(71) Applicant: Raytheon Company, Arlington, VA (US)

(72) Inventors: Fernando Ma, Tucson, AZ (US); Mark R. Northrup, Marana, AZ (US); Ricardo R. Rodriguez, Tucson, AZ (US); Farshad Moghimi, Tucson, AZ (US); Mahmoud Yazdani, Vail, AZ (US)

(21) Appl. No.: 19/355,574

(22) Filed: Oct. 10, 2025

Related U.S. Application Data
(60) Provisional application No. 63/706,405, filed on Oct. 11, 2024.

(51) Int. Cl. H05K 1/181; B33Y 80/00; H05K 3/46; H05K 5/02; H05K 7/14; B33Y 10/00

(52) U.S. Cl. CPC H05K 1/181; B33Y 80/00; H05K 3/4644; H05K 5/0217; H05K 7/1427; B33Y 10/00

(57) ABSTRACT

An additively manufactured electronics packaging assembly including a build substrate formed from a plurality of additively printed layers. One or more additively printed electrical interconnects can be positioned within the plurality of layers. The assembly can include an electronics housing built along the build substrate. The electronics housing can include one or more additively printed walls extending around a component cavity and a housing lid enclosing the cavity. One or more electronic components can be positioned within the cavity and can be electrically connected to the additively printed electrical interconnects.

### CLAIM OF PRIORITY

This patent application claims the benefit of priority to U.S. Provisional Application Serial No. 63/706,405, filed Oct. 11, 2024, which is incorporated by reference herein in its entirety.

### BACKGROUND

Additive manufacturing, also known as 3D printing, is a manufacturing process that forms three-dimensional objects by depositing materials layer by layer until a final product is built. This technique contrasts with traditional subtractive manufacturing methods, which typically involve cutting away material from a larger block. For example, in additive manufacturing layers of material are built up, layer by layer, according to designs generated with computer-aided design technology. During the build up of material, voids, recesses, cavities, and the like are formed by omitting material in those areas during printing.

In some examples, an additively manufactured product can be formed by designing a computer model of the desired final product. The design can be converted to a format that can be communicated to a 3D printer. The 3D printer can be instructed to deposit, or print, material, layer by layer, according to the locations indicated in the computer model. In some examples, the 3D printer forms solid structures, porous structures or structures having openings or cavities. In other examples, the 3D printer prints products having enclosed cavities. The 3D printer can also print components for a final product; for example, components are coupled with separate 3D printed components or components that have not been 3D printed.

Some examples of additive manufacturing, or 3D printing, technologies include fused deposition modeling (FDM), stereolithography (SLA), selective laser sintering (SLS), direct metal laser sintering (DMLS), and binder jetting. This list is not an exhaustive list of additive manufacturing technologies, but an example of methods implemented to manufactured products by a repeated addition of material. In some examples, a combination of methods can be used to form an additively manufactured product.

Fused deposition modeling is, for example, a process that includes melting filaments, such as polymers, metals, ceramics, glass, or the like. The melted filaments are then extruded from a nozzle. In an example, the extruded, melted filaments are deposited layer by layer on a plate. Each layer can be subsequently placed on a previous layer according to the design communicated to the 3D printer.

Stereolithography is an example of a form of 3D printing that uses a photochemical process. A light can be applied to chemicals to cross-link and form polymers. In some examples, an ultraviolet (UV) light can be focused on a polymer resin. As the light is, for instance, applied to the polymer, the polymer solidifies. The polymers are bonded to, for example, form a three-dimensional solid.

Selective Laser Sintering (SLS) is an example of an additive manufacturing technique that uses, for example, a high-power laser to selectively fuse powdered materials into a desired three-dimensional shape. In this process, a thin layer of powder can be spread over a build platform. The laser then traces the cross-section of the object being built, sintering the powder particles, and bonding them together. In some examples, the powdered material is a metal, ceramic, polymer, or glass.

Binder jetting is an example of an additive manufacturing process that can be used to form three-dimensional objects by selectively depositing a liquid binding agent onto layers of powder material. In this technique, a print head moves across a bed of powder, applying droplets of binder to bond the particles together in the desired shape. This process can repeat layer by layer until the entire object is formed. Once the printing is complete, the part can be cured to strengthen the bonds between particles.

Additive manufacturing can be used in a wide range of industries due to its versatility and ability to form complex geometries. For example, in the military, aerospace and defense sectors, additive manufacturing can be used for producing lightweight components and components that can withstand harsh environments. In another example, the automotive industry leverages additive manufacturing for rapid prototyping and creating specialized parts. Additionally, additive manufacturing can be utilized in the oil and gas industry for forming specialized tools and components that can operate in challenging conditions. The marine industry can also benefit from additive manufacturing technology for producing corrosion-resistant parts. In another example, additive manufacturing also is applicable in consumer goods, allowing for personalized products and reducing waste in manufacturing processes.

### SUMMARY

An additively manufactured electronics packaging can address challenges in some currently implemented electronics packaging technologies. For example, an additively manufactured electronics packaging can reduce potential environmental effects and leak paths. In other examples, the additively manufactured electronics packaging can be implemented in systems that can be subject to harsh environments.

For example, an additively manufactured electronics packaging assembly can include a build substrate formed from one or more additively printed layers. In some examples, the additively manufactured electronics packaging assembly can include one or more additively printed layers that can incorporate, include, one or more electrical interconnects, or form one or more electrical traces. The one or more electrical interconnects can be positioned within the one or more additively printed layers during the process of printing the one or more additively printed layers. For example, an additively manufactured build substrate, or foundation of the additively manufactured electronics packaging, can include printed layers that can include additively printed electrical interconnects, or traces, which are positioned within the build substrate.

The additively manufactured electronics packaging assembly can include an electronics housing coupled to the build substrate. In an example, the electronics housing is combined with the build substrate. For example, the electronics housing can be additively manufactured as a unitary structure with the additively manufactured build substrate. The electronics housing can be formed from additively printed walls extending around a component cavity. The component cavity can be formed to house, retain, position or the like any of a number of electrical components within the electronics housing. In an example, one or more electronic components positioned within the component cavity are electrically connected to at least one portion of an additively printed electrical interconnect.

A housing lid can be coupled with one or more of the additively printed walls and can enclose the component cavity. The housing lid can be coupled with one or more of the additively manufactured walls. The housing lid can be an additively manufactured component. In another example the housing lid can be formed by molding, extruding, or other method.

The additively printed electronics packaging assembly can seal the electronic components positioned within the additively printed electronics housing from the external environment. In an example, the additively printed walls extend from the build substrate. In another example, the housing lid is coupled, adhered, or additively printed on the one or more additively printed walls to form a sealed environment within the component cavity. For example, the arrangement of the one or more additively printed walls and the housing lid coupled with the additively printed walls seals the one or more electrical components within the electronics housing.

The above and following description, while indicating various examples of the concepts, is given by way of illustration and not of limitation. Many substitutions, modifications, additions, or rearrangements may be made within the scope of the disclosed examples, and the examples discusses can include substitutions, modifications, additions, or rearrangements.

### BRIEF DESCRIPTION OF THE DRAWINGS

FIGS. 1A and 1B illustrate examples of a schematic of an additively manufactured electronics packaging according to at least one example of the present disclosure.

FIG. 2 illustrates an example of a schematic additively manufactured electronics packaging assembly according at least one example of the present disclosure.

FIG. 3 illustrates an example of a method of forming an additively manufactured electronics packaging assembly according to at least one example of the present disclosure.

### DETAILED DESCRIPTION

Computer chips, electronic components and the like can employ packaged technology to provide an electronics systems that can be used to implement an overall system. For example, an electronics packaging can be an enclosure for electronic devices to protect electrical components. Electronic packages can protect electronic components, for example, capacitors, resistors, memory systems, and electrical interconnects from the exterior environment. In some examples, such as a semiconductor package, the design can be implemented to protect individual components that are fabricated on substrates (e.g., wafers, silicon, glass). The electronics packaging can provide a way of connecting the components to another system, such as a printed circuit board.

In some examples, the electronics packaging includes several components formed from one or more materials. For instance, a hybrid electronic packaging is a package that combines active chip devices with passive components. In some examples, the components are electrically insulated from the outer environment such that they are packaged in a hermetically sealed environment. For example, the internal components are housed in a low-pressure environment that has been sealed to minimize infiltration from external environmental material such as particulates, moisture or the like that can inhibit, damage, or destroy the operation of the internal electrical components.

In some examples, sealing the electrical components, such as the electrical interconnects, can be accomplished with glass-to-metal (GMS) seals, brazing or welding. For example, a GMS reduces a likelihood of external environmental material (e.g., water, particulates) from infiltrating into the internal structures of the packaging. In some examples, the seal is a hermetic seal that is capable of maintaining a low-pressure environment or electrical insulation. In some situations, the GMS can be subject to degradation. Degradation of the GMS can cause failures in the electronic system, packaging, or the like. For example, an improper GMS can cause electrical signal leakage, change the internal environment of the electronic packaging, or allow infiltration of environmental material into the packaging.

In some examples, there can be more than one GMS on an electronic package. For instance, there can be multiple electrical leads, connectors or the like that extend from the electronic package. At each point where the electrical lead or connector extends from the electronic package, there can be a GMS. In some situations, each of these points can be a location where there can be a failure of the electronic package protection.

In other examples, failures in the electronics package can occur at interfaces between structural components of the electronics package. For instance, there can be a leak path at the interface between a lid or at intersection of the electronic housing or frame components with the substrate. In some examples, the electronics housing, frame, or the like, is welded to the substrate and the lid is welded, adhered, joined with the electronics housing. The areas where components are welded or brazed together can be other failure points or leakage points.

Some examples of a packaging system can include additively manufacturing at least a component of the electronics packaging. For example, additive manufacturing, or 3D printing, is implemented to form a build substrate as the foundational component of the electronics packaging. Other components of the electronics packaging can then be coupled, attached, adhered, fastened, inserted, or included in or with the build substrate. In some examples, the majority of the electronics package is formed from an additive manufacturing process.

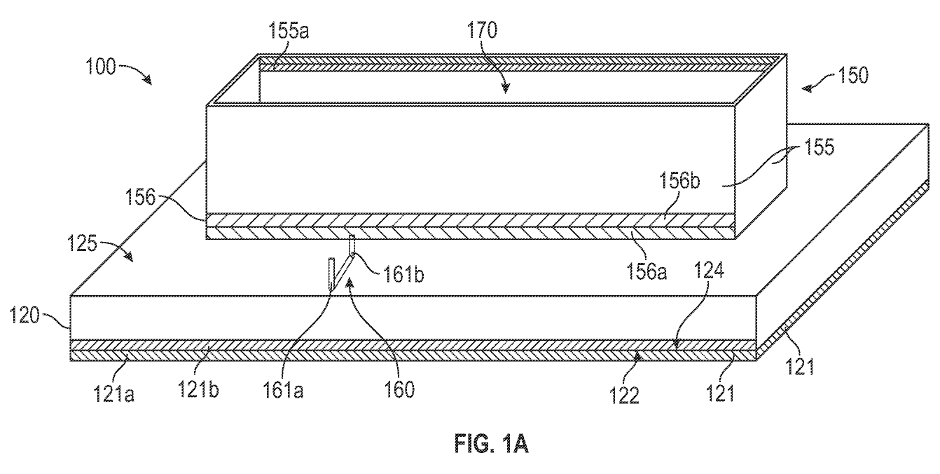

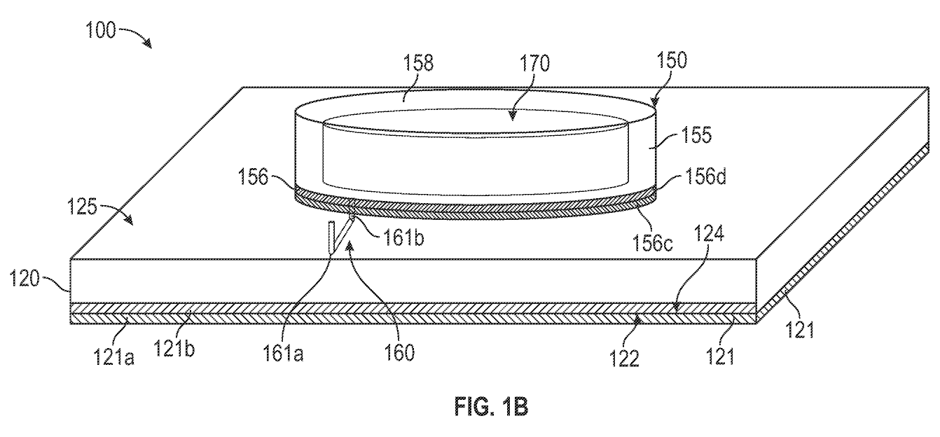

Illustrated in FIG. 1A is an example of an additively manufactured electronics packaging 100. The additively manufactured electronics packaging 100 can include a build substrate 120 as a foundational or base component. The build substrate 120 can support additional components of the additively manufactured electronics packaging 100. The build substrate 120 can support an electronics housing 150. The build substrate 120 can also support one or more electrical interconnects 160.

In an example, the additively manufactured build substrate 120 includes one or more additively printed layers 121. The one or more additively printed layers 121 can be formed from one or more of ceramic, glass, metal, or polymer. For example, the one or more additively printed layers 121 can include ceramic. In another example, the one or more additively printed layers 121 can include a first additively printed layer 121a that includes a ceramic and a second additively printed layer 121b that includes a polymer. In yet another example, the one or more additively printed layers 121 can include a first additively printed layer 121a that includes a ceramic and a second additively printed layer 121b that includes a metal. Optionally, the additively printed layers 121 can include one or more of first additively printed layer 121a stacked, or layered, on another followed by one or more of second additively printed layer 121b. Including multiple one or more additively printed layers 121 formed from any number of different materials can also be implemented informing the build substrate 120.

The first additively printed layer 121a can include a first layer interface 122 as an outer facing surface of the first additively printed layer 121a. The first layer interface 122 can be positioned to face the second additively printed layer 121b. The second additively printed layer 121b can include a second layer interface 124 as an outer facing surface of the second additively printed layer 121b. The first additively printed layer 121a and the second additively printed layer 121b are, for example, oriented with the second additively printed layer 121b to join with the first additively printed layer 121a. For instance, the second layer interface 124 can be deposited (e.g., additively printed) to be intermingled with the first layer interface 122. In examples, subsequent one or more additively printed layers 121 are repeatedly deposited on a previously deposited one or more additively printed layers 121 until the form of the build substrate 120 is completed or reaches a predetermined structure.

The position where the one or more additively printed layers 121 (e.g., subsequent first additively printed layers and second additively printed layers) meet, join, or are otherwise coupled, the one or more additively printed layers 121 can be intermingled. Intermingling of the one or more additively printed layers 121 can include a fluid, liquid or powder deposition of additively printed material at least partially combining or joining with the previously deposited additively printed layer. For example, at least some of the subsequent deposited additively printed layer (e.g., the second additively printed layer 121b) is welded, fused, bonded with the previously deposited (e.g., the first additively printed layer 121a).

In an example, the one or more additively printed layers 121 includes additively printed insulating layers. For example, the one or more additively printed layers 121 includes materials that are electrically insulating such that electricity flowing through the additively printed material as part of the electronics packaging are protected from the external environment.

In an example, the one or more additively printed layers 121 includes additively printed insulating layers that has one or more additively printed electrical interconnects 160, or traces that can support an electrical interface. For instance, the one or more electrical interconnects 160 is integrated within the one or more additively printed layers 121. The one or more electrical interconnects 160, as additively printed electrical interconnects, can be printed in concert to printing, or depositing, the one or more additively printed layers 121. For example, the one or more electrical interconnects 160 can be printed to be positioned at predetermined locations of a layer instead of the additively printed layer 121 material. The one or more electrical interconnects 160 can be additively printed within one layer of the one or more additively printed layers 121. In another example, the one or more electrical interconnects 160 is printed to extend through more than one layer of the one or more additively printed layers 121.

The one or more electrical interconnects 160 can include a first end portion 161a and a second end portion 161b. The first end portion 161a and the second end portion 161b can extend through more than one layer of the one or more additively printed layers 121. In an example, at least part of one of the first end portion 161a or the second end portion 161b is additively printed to extend through more than one layer of the one or more additively printed layers 121 to be exposed from the build substrate 120. For instance, the first end portion 161a and the second end portion 161b are each additively printed to be coupled or connected with an electrical component.

The one or more electrical interconnects 160 can be printed as a deposition of a metal or a conductive adhesive, such that the one or more electrical interconnects 160 is integrated with the additively printed layer. For example, a deposition of copper, aluminum, nickel, alloys, or other metals that are suitable for the purpose can form the one or more electrical interconnects 160. In another example, a deposition of a conductive adhesive can include silver, graphite or other conductive material mixed with an adhesive.

An example of the additively manufactured electronics packaging 100 includes the electronics housing 150. The electronics housing 150, for example, is positioned on a surface 125 of the build substrate 120. For instance, the surface 125 is a top surface of the build substrate 120. The electronics housing 150 can be formed to be additively printed as an extension of the build substrate 120. In another example, the electronics housing 150 is additively printed from a different material such that it is coupled along the build substrate 120. The electronics housing 150 can be additively printed as a unitary structure with the build substrate 120. For example, the electronics housing 150 can be considered one structure without any breaks, gaps, recesses, or the like, between the electronics housing 150 and the build substrate 120.

The electronics housing 150 can include one or more additively printed walls 155. The one or more additively printed walls 155 and at least one of the one or more additively printed layers 121 can be printed in concert. For example, at least one layer 156 of the one or more additively printed walls 155 can be printed continuously with the one or more additively printed layers 121 such that the one layer 156 is a continuous structure with the build substrate 120. In another example, the one layer 156 of the one or more additively printed walls 155 can be printed, or deposited, shortly after substantially completing printing the one or more additively printed layers 121, such as within a few minutes after, less than one minute after, less than five seconds after, less than 1 second after. In an example, the one layer 156 can be additively printed while the one or more additively printed layers 121 is still being additively printed. In even further examples, more than one layer of the additively the one or more additively printed walls 155 can be printed while other portions of the build substrate 120 are printed.

The one or more additively printed walls 155 can be printed as one continuous wall, such as a rounded form 158 (e.g., circle, ellipse, oval or the like) as illustrated in FIG. 1B. For example, in some situations the design of the electronics housing 150 includes a rounded form to reduce the number of corners of the electronics housing 150. In another example, the one or more additively printed walls 155 can be additively printed as a polygon as illustrated in the example additively manufactured electronics packaging 100 of FIG. 1A. For example, the one or more additively printed walls 155 are printed to form a rectangle. The one or more additively printed walls 155 can be printed according to the purpose of the electronics housing 150.

In some examples, the one or more additively printed walls 155 are printed using more than one material. For instance, the one or more additively printed walls 155 includes additively printed insulating layers, such as a dielectric material. The one or more additively printed walls 155 can include one layer 156 of a first wall layer 156a including a first insulating material and a second wall layer 156b of a second insulating material. The one or more additively printed walls 155 can be formed in a rounded form 158 that can include a first additively printed ring layer 156c and a second additively printed ring layer 156d. In an example, the first wall layer 156a or the first additively printed ring layer 156c can include a polymer, such as a dielectric material, and the second wall layer 156b or second additively printed ring layer 156d can include a ceramic material. In other examples, the one or more additively printed walls 155 (of any form) can include more interior wall layers 155a. Each of the one or more additively printed walls 155 and the more interior wall layers 155a can be formed, printed, or the like from the same material or different materials.

The one or more additively printed walls 155 can extend around a component cavity 170. For example, the one or more additively printed walls 155 can formed (e.g., deposited) to be spaced from opposing portions, or opposing walls. The one or more additively printed walls 155 can be positioned to surround, extend around, or define the component cavity 170 so one or more components can be housed, placed or the like within the component cavity 170.

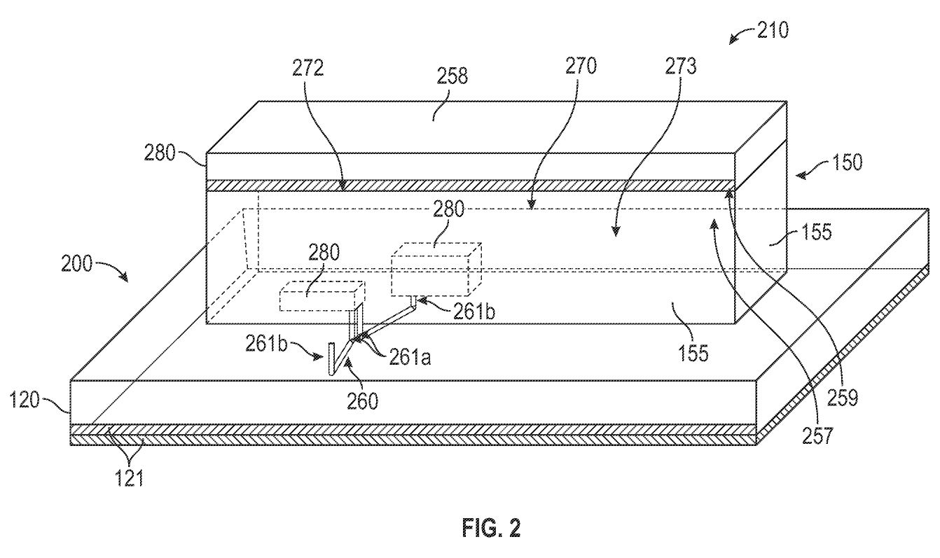

As illustrated in FIG. 2, the additively manufactured electronics packaging assembly 210 can include the build substrate 120 and the electronics housing 150 as a unitary structure. The electronics housing 150 can be coupled with the build substrate 120 such that the electronics housing 150 extends from the build substrate 120. In an example, the electronics housing 150 can be combined with the build substrate 120. The electronics housing 150, for example, is printed, deposited, or otherwise additively manufactured in concert with the build substrate 120. For instance, a short time after (e.g., less than five minutes, less than one minute, less than ten seconds, less than one second) the build substrate 120 is completed (e.g., partially set, fully set, or the like) the electronics housing 150 is printed on the build substrate 120.

In an example, the electronics housing 150 is formed from one or more additively printed walls 155. The one or more additively printed walls 155 extend around a component cavity 270. The component cavity 270 can be a recess, opening, space or the like that has a profile that can retain, house, store, receive or the like, one or more electronic components 280. The one or more electronic components 280 can include computer chip components (e.g., resistors, capacitors, memory, or the like) or optic devices such as photonics (e.g., laser sending and receiving devices). The one or more electronic components 280 can be positioned within the component cavity 270 at specified locations according to the purpose. In an example, the one or more electronic components 280 are coupled with another of the one or more electronic components 280 or are coupled with elements external to the additively manufactured electronics packaging assembly 210.

In another example of an additively manufactured electronics packaging 200 illustrated in FIG. 2, the build substrate 120 can include one or more electrical interconnects 260. The one or more electrical interconnects 260 can be similar to the one or more electrical interconnects 160. For example, the one or more electrical interconnects 260 can be positioned, additively printed, disposed, deposited, integrated or the like within the build substrate 120. In another example, the build substrate 120 can be formed to include electrical traces where one or more electrical interconnects 260 can be positioned. Optionally, the one or more electrical interconnects 260 can be additively printed within or on the build substrate 120. For example, the one or more electrical interconnects 260 can be printed as a deposition of a metal or conductive adhesive integrated into the one or more electrical interconnects 160. The one or more electrical interconnects 260 can be integrated such that the one or more electrical interconnects 260 are positioned to be electrically connected with at least one of the one or more electronic components 280. In an example, at least a first portion 261a of the one or more electrical interconnects 260 is coupled with, or electrically connected with the one or more electronic components 280 and a second portion 261b of the one or more electrical interconnects 160 is coupled with or electrically connected with an electrical component outside of the component cavity 270. In another example, the first portion 261a is electrically connected with one of the one or more electronic components 280 and the second portion 261b is electrically connected with another of the one or more electronic components 280 within the component cavity 270.

The additively manufactured electronics packaging assembly 210 can include a housing lid 258. The housing lid 258 can enclose, seal, or isolate the component cavity 270 from exterior environmental materials or maintain the environment within the component cavity 270. The housing lid 258 can be coupled along the one or more additively printed walls 155 (either in a polygonal form as illustrated in FIG. 1A, 2 or rounded as illustrated in FIG. 1B). In an example, the housing lid 258 can be coupled with an adhesive, welding, soldering, additively printing or the like. For example, the housing lid 258 is an additional component for the additively manufactured electronics packaging assembly 210 that is provided separately from the unitary form of the additively manufactured electronics packaging assembly 210. The housing lid 258 can be coupled with at least one wall of the one or more additively printed walls 155 to seal the component cavity 270. In an example, the housing lid 258 is coupled with upper portions 257 of the one or more additively printed walls 155. For instance, the housing lid 258 can be coupled with interior portions 273 of the one or more additively printed walls 155.

The housing lid 258 can be coupled with the one or more additively printed walls 155 to hermetically seal the component cavity 270. In an example, the one or more electronic components 280 are housed within the electronics housing 150 with the housing lid 258 covering a housing opening 272, defined by the one or more additively printed walls 155, of the component cavity 270. The housing lid 258 can assist in maintaining the environment within the component cavity 270. For instance, the housing lid 258 can assist in reducing infiltration of environmental material (e.g., moisture, dust, particulates) into the component cavity 270. In an example, the housing lid 258 can reduce moisture, such as humidity, from infiltrating into the component cavity 270. In another example, the housing lid 258 can reduce electrical leakage, such as signal loss, from the one or more electronic components 280. The housing lid 258 can also assist in maintaining specific pressures within the component cavity 270. For instance, the housing lid 258 can assist in maintaining a low-pressure environment within the component cavity 270.

The housing lid 258 can be formed with additive printing as a separate component. In another example, the housing lid 258 can be formed with additive printing on the one or more additively printed walls 155. The housing lid 258 can be formed from one or more housing lid layers 259. The one or more housing lid layers 259 can be formed from similar materials as the 155, such as ceramics, polymers, glass, metals, or a combination of materials. The housing lid 258 can also be molded, extruded, machined, or otherwise formed to have a profile or dimensions that corresponds with the housing opening 272.

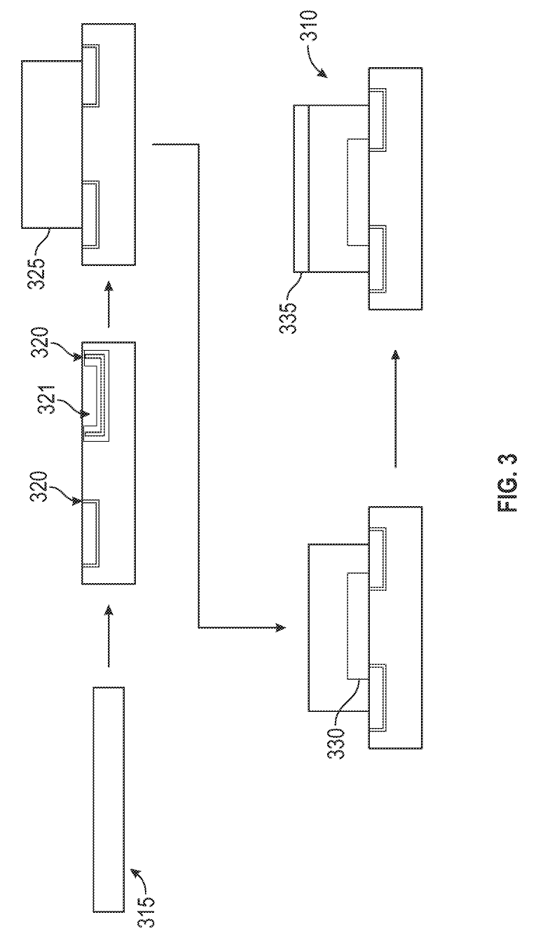

Illustrated in FIG. 3 is a schematic that illustrates an example method of forming an additively manufactured electronic package assembly 310. The method includes building a build substrate 315. Building the build substrate 315 includes depositing a first layer of a material on a build plate of an additive manufacturing system. The first layer can be deposited with one of fused deposition modeling, stereolithography, selective laser sintering or binder jetting (hereinafter additive printing). In an example, the build substrate 315 includes additively printing a stack of layers on the first layer. For instance, the stack of layers includes one or more subsequent layers with each layer having a layer interface. The layer interface can, for example, face, be bonded with a subsequent layer having a corresponding layer interface. Each of the layer interfaces can intermingle with the adjacent, or subsequent, layer interface. In an example, additional layers are added to previous layers according to a predetermined design. The one or more layers forming the stack of layers can include depositions, or printing, layers that include different materials. For example, a first layer can be ceramic, and the second layer can be a polymer. In some examples, there are one or more layers of the same material followed by one or more layers of a different material.

Optionally, while additively printing the stack of layers to form the build substrate 315, one or more electrical interconnects 320 are integrated or incorporated with the additively printed layers. In an example, the one or more interconnects 320 can include electrical traces 321 in which an electrical interconnect is positioned. In an example, the one or more electrical interconnects 320 are deposited in concert with the additively printed layers. For instance, the additively printed layer material is not deposited in locations where the additively printed one or more electrical interconnects 320 is to be positioned or printed. In an example, the one or more electrical interconnects 320 is additively printed from one or more of a metal or a conductive adhesive. The one or more electrical interconnects 320 can be printed with a first end portion and a second end portion. For example, at least one of the first end portion and the second end portion are exposed from the build substrate 315.

After the build substrate 315 is formed, or while the build substrate 315 is being formed, an additively printed housing 325 is formed on the build substrate 315. For example, the additively printed housing 325 is additively printed on the build substrate 315. The additively printed housing 325 with the build substrate 315 is formed as a unitary structure. For example, the additively printed housing 325 is continuously built with the build substrate 315. The additively printed housing 325 can be formed from the same material as the build substrate 315. In another example, the additively printed housing 325 can be formed from a different material as the build substrate 315. In yet another example, the additively printed layers of the additively printed housing 325 can be different as the additively printed housing 325 is additively printed.

In an example, the additively printed housing 325 is printed from one or more additively printed walls. The additively printed walls can extend around a component cavity. For instance, the additively printed walls can define a cavity, opening, space, recess, or the like. The cavity can have a dimension sized to retain one or more electronic components 330. The one or more electronic components 330 can be positioned or retained within the component cavity to be electrically connected with at least one of a first end portion or the second end portion of the one or more electrical interconnects 320.

The additively printed housing 325 can be sealed with the one or more electronic components 330 with a housing lid 335. The housing lid 335 can be coupled with the one or more of the additively printed walls. In an example, the housing lid 335 is additively printed on the one or more additively printed walls. The housing lid 335 can be a separate additively printed component that is adhered, welded, fastened, or otherwise coupled with the one or more additively printed walls.

In an example, the housing lid 335 seals the component cavity when coupled with the one or more additively printed walls. For instance, the housing lid 335 isolates the components, such as the electronic components, positioned or retained within the cavity from an environment exterior to the additively manufactured electronic package assembly 310. The housing lid 335 in combination with the unitary form of the build substrate 315 with the additively printed housing 325 reduces exterior environmental material from infiltrating into the component cavity. For example, once the housing lid 335 is coupled with the one or more additively printed walls, the components are isolated from moisture, particulates, or other matter.

The housing lid 335 can also maintain the internal environment within the cavity. In an example, the housing lid 335 reduces moisture, such as humidity, from infiltrating into the component cavity. For instance, the housing lid 335 in combination with the unitary form of the build substrate 315 with the additively printed housing 325 reduces electrical leakage from the additively printed housing 325. The electrical leakage could be signal leakage from the electrical components housed or retained within the component cavity.

The combination of the housing lid 335 adhered, printed, or otherwise coupled with the additively printed housing 325 and the additively printed housing 325 printed on the build substrate 315 reduces areas where external environmental material can infiltrate into the component cavity and also the environment within the component cavity from escaping.

### Aspects

Aspect 1 can include subject matter such as an additively manufactured electronics packaging assembly comprising: a build substrate including; one or more additively printed layers; and one or more additively printed electrical interconnects positioned within the one or more additively printed layers; and an electronics housing coupled along the build substrate, the electronics housing includes: one or more additively printed walls extending around a component cavity; and a housing lid coupled along the one or more additively printed walls and enclosing the component cavity; and one or more electronic components within the component cavity, the one or more electronic components electrically connected with the additively printed electrical interconnects; and wherein the one or more additively printed walls and the housing lid of the electronics housing are configured to seal the one or more electronic components from an environment exterior to the electronics housing.

Aspect 2 can include, or can optionally be combined with the subject matter of Aspect 1, to optionally include the one or more additively printed walls and at least one of the additively printed layers or the additively printed electrical interconnects are additively printed in concert.

Aspect 3 can include, or can optionally be combined with the subject matter of one or any combination of Aspects 1 or 2 to optionally include the one or more additively printed layers each include a layer interface; wherein the layer interface of each of the one or more additively printed layers intermingle.

Aspect 4 can include, or can optionally be combined with the subject matter of one or any combination of Aspects 1 to 3 to optionally include the one or more additively printed walls includes: a first additively printed layer including a ceramic material; and a second additively printed layer including a polymer material.

Aspect 5 can include, or can optionally be combined with the subject matter of one or any combination of Aspects 1 to 4 to optionally include the one or more additively printed walls includes a plurality of additively printed ring layers including: at least a first additively printed ring layer; and a second additively printed ring layer overlying the first additively printed ring layer.

Aspect 6 can include, or can optionally be combined with the subject matter of one or any combination of Aspects 1 to 5 to optionally include each of the one or more additively printed layers and the housing lid includes a ceramic, a glass, a metal, or a polymer.

Aspect 7 can include, or can optionally be combined with the subject matter of one or any combination of Aspects 1 to 6 to optionally include the housing lid is coupled with the one or more additively printed walls with an adhesive.

Aspect 8 can include, or can optionally be combined with the subject matter of one or any combination of Aspects 1 to 7 to optionally include the housing lid is additively printed on the one or more additively printed walls.

Aspect 9 can include, or can optionally be combined with the subject matter of one or any combination of Aspects 1 to 8 to optionally include the one or more additively printed electrical interconnects is integrated with the additively printed layers.

Aspect 10 can include subject matter such as an additively manufactured electronics packaging comprising: a build substrate including; one or more additively printed insulating layers; and one or more additively printed electrical interconnects positioned within the one or more additively printed insulating layers including a first end portion and a second end portion; and an electronics housing extending from the build substrate, the electronics housing including one or more additively printed walls extending around a component cavity; wherein the first end portion of the one or more additively printed electrical interconnects is positioned within the electronics housing and the second end portion of the one or more additively printed electrical interconnects is positioned outside of the electronics housing.

Aspect 11 can include, or can optionally be combined with the subject matter of one or any combination of Aspect 10 to optionally include a housing lid coupled along the one or more additively printed walls and enclosing the component cavity; wherein the one or more additively printed walls and the housing lid are configured to isolate the component cavity from external environment infiltration.

Aspect 12. can include, or can optionally be combined with the subject matter of one or any combination of Aspects 10 or 11 to optionally include wherein the one or more additively printed walls and at least one of the additively printed insulating layers or the additively printed electrical interconnects are additively printed in concert.

Aspect 13 can include, or can optionally be combined with the subject matter of one or any combination of Aspects 10 - 12 to optionally include the one or more additively printed electrical interconnects is integrated with the additively printed layers.

Aspect 14 can include, or can optionally be combined with the subject matter of one or any combination of Aspects 10 - 13 to optionally include the one or more additively printed layers includes: a first additively printed layer; and a second additively printed layer; wherein the each of the first additively printed layer includes a first layer interface and the second additively printed layer includes a second layer interface; wherein the first layer interface and the second layer interface are oriented to be intermingled.

Aspect 15 can include, or can optionally be combined with the subject matter of one or any combination of Aspects 10 - 14 to optionally include a housing lid coupled with the one or more additively printed walls; wherein each of the one or more additively printed insulating layers and the housing lid includes a ceramic, a glass, a metal or a polymer.

Aspect 16 can include, or can optionally be combined with the subject matter of one or any combination of Aspects 10 - 15 to optionally include the electronics housing is configured to isolate the component cavity from external environmental infiltration.

Aspect 17 can include subject matter such as a method of forming an additively manufactured electronics packaging assembly comprising: forming a build substrate including: depositing a first layer of a material on a build plate; and additively printing a stack of layers on the first layer; wherein the stack of layers includes one or more subsequent layers, each subsequent layer including a layer interface, the layer interface configured to be intermingled with a layer interface of a subsequent layer of the one or more subsequent layers; and while additively printing the stack of layers, incorporating one or more electrical interconnects within the stack of layers, each of the one or more the electrical interconnects including a first end portion and a second end portion; additively printing an electronics housing along the build substrate including: depositing one or more wall layers on the build substrate to form a printed wall extending around a component cavity; and sealing the electronics housing with a housing lid by coupling the housing lid with one or more printed walls.

Aspect 18. can include, or can optionally be combined with the subject matter of Aspect 17 to optionally include incorporating an electrical interconnect includes additively printing the electrical interconnect; wherein the electrical interconnect includes one of a metal or a conductive adhesive.

Aspect 19 can include, or can optionally be combined with the subject matter of one or any combination of Aspects 17 or 18 to optionally include positioning one or more electronic components within the component cavity; electrically connecting the one or more electronic components with at least one of the first end portion or the second end portion of the one or more electrical interconnects; and sealing the one or more electronic components within the component cavity, including: isolating the one or more electronic components from an environment exterior to the electronics housing.

Aspect 20 can include, or can optionally be combined with the subject matter of one or any combination of Aspects 17 - 19 to optionally include additively printing the electronics housing continuously with the build substrate.

The above description includes references to the accompanying drawings, which form a part of the detailed description. The drawings show, by way of illustration, specific embodiments in which the disclosed concepts can be practiced. These embodiments are also referred to herein as “aspects” or “examples.” Such aspects or example can include elements in addition to those shown or described. However, the description also contemplates aspects or examples in which only those elements shown or described are provided. Moreover, the description also contemplates aspects or examples using any combination or permutation of those elements shown or described (or one or more features thereof), either with respect to a particular aspects or examples (or one or more features thereof), or with respect to other Aspects (or one or more features thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel,” “perpendicular,” “round,” or “square,” are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

The above description is intended to be illustrative, and not restrictive. For example, the above-described aspects or examples (or one or more aspects thereof) may be used in combination with each other. Other embodiments can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, subject matter may lie in less than all features of a particular disclosed embodiment. Thus, the following claims are hereby incorporated into the Detailed Description as aspects, examples, or embodiments, with each claim standing on its own as a separate embodiment, and it is contemplated that such embodiments can be combined with each other in various combinations or permutations. The scope of the disclosed concepts should be determined with reference to the appended claims, along with the full scope of equivalents to which such claims are entitled.

What is claimed is:

1. An additively manufactured electronics packaging assembly comprising:
a build substrate including;
one or more additively printed layers; and
one or more additively printed electrical interconnects positioned within the one or more additively printed layers; and
an electronics housing coupled along the build substrate, the electronics housing includes:
one or more additively printed walls extending around a component cavity; and
a housing lid coupled along the one or more additively printed walls and enclosing the component cavity; and
one or more electronic components within the component cavity, the one or more electronic components electrically connected with the additively printed electrical interconnects; and
wherein the one or more additively printed walls and the housing lid of the electronics housing are configured to seal the one or more electronic components from an environment exterior to the electronics housing.

2. The additively manufactured electronics packaging assembly of claim 1, wherein the one or more additively printed walls and at least one of the additively printed layers or the additively printed electrical interconnects are additively printed in concert.

3. The additively manufactured electronics packaging assembly of claim 1, wherein the one or more additively printed layers each include a layer interface;
wherein the layer interface of each of the one or more additively printed layers intermingle.

4. The additively manufactured electronics packaging assembly of claim 3, wherein the one or more additively printed walls includes:
a first additively printed layer including a ceramic material; and
a second additively printed layer including a polymer material.

5. The additively manufactured electronics packaging assembly of claim 1, wherein the one or more additively printed walls includes a plurality of additively printed ring layers including:
at least a first additively printed ring layer; and
a second additively printed ring layer overlying the first additively printed ring layer.

6. The additively manufactured electronics packaging assembly of claim 1, wherein each of the one or more additively printed layers and the housing lid includes a ceramic, a glass, a metal, or a polymer.

7. The additively manufactured electronics packaging assembly of claim 1, wherein the housing lid is coupled with the one or more additively printed walls including an adhesive.

8. The additively manufactured electronics packaging assembly of claim 1, wherein the housing lid is additively printed on the one or more additively printed walls.

9. The additively manufactured electronics packaging assembly of claim 1, wherein the one or more additively printed electrical interconnects is configured to be integrated with the additively printed layers.

10. An additively manufactured electronics packaging comprising:
a build substrate including;
one or more additively printed insulating layers; and
one or more additively printed electrical interconnects positioned within the one or more additively printed insulating layers including a first end portion and a second end portion; and
an electronics housing extending from the build substrate, the electronics housing including one or more additively printed walls extending around a component cavity;
wherein the first end portion of the one or more additively printed electrical interconnects is positioned within the electronics housing and the second end portion of the one or more additively printed electrical interconnects is positioned outside of the electronics housing.

11. The additively manufactured electronics packaging of claim 10 including:
a housing lid coupled along the one or more additively printed walls and enclosing the component cavity;
wherein the one or more additively printed walls and the housing lid are configured to isolate the component cavity from external environment infiltration.

12. The additively manufactured electronics packaging of claim 10, wherein the one or more additively printed walls and at least one of the additively printed insulating layers or the additively printed electrical interconnects are additively printed in concert.

13. The additively manufactured electronics packaging of claim 10, wherein the one or more additively printed electrical interconnects is integrated with the additively printed layers.

14. The additively manufactured electronics packaging of claim 10, wherein the one or more additively printed layers includes:
a first additively printed layer; and
a second additively printed layer;
wherein the each of the first additively printed layer includes a first layer interface and the second additively printed layer includes a second layer interface;
wherein the first layer interface and the second layer interface are oriented to be intermingled.

15. The additively manufactured electronics packaging of claim 10, including a housing lid coupled with the one or more additively printed walls;
wherein each of the one or more additively printed insulating layers and the housing lid includes a ceramic, a glass, a metal, or a polymer.

16. The additively manufactured electronics packaging of claim 10, wherein the electronics housing is configured to isolate the component cavity from external environmental infiltration.

17. A method of forming an additively manufactured electronics packaging assembly comprising:
forming a build substrate including:
depositing a first layer of a material on a build plate; and
additively printing a stack of layers on the first layer;
wherein the stack of layers includes one or more subsequent layers, each subsequent layer including a layer interface, the layer interface configured to be intermingled with a layer interface of a subsequent layer of the one or more subsequent layers; and
while additively printing the stack of layers, incorporating one or more electrical interconnects within the stack of layers, each of the one or more the electrical interconnects including a first end portion and a second end portion;
additively printing an electronics housing along the build substrate including:
depositing one or more wall layers on the build substrate to form a printed wall extending around a component cavity; and
sealing the electronics housing with a housing lid by coupling the housing lid with one or more printed walls.

18. The method of forming the additively manufactured electronics packaging assembly of claim 17, wherein incorporating an electrical interconnect includes additively printing the electrical interconnect;
wherein the electrical interconnect includes one of a metal or a conductive adhesive.

19. The method of forming the additively manufactured electronics packaging assembly of claim 17, including:
positioning one or more electronic components within the component cavity;
electrically connecting the one or more electronic components with at least one of the first end portion or the second end portion of the one or more electrical interconnects; and
sealing the one or more electronic components within the component cavity, including:
isolating the one or more electronic components from an environment exterior to the electronics housing.

20. The method of forming the additively manufactured electronics packaging assembly of claim 17, includes:
additively printing the electronics housing continuously with the build substrate.
